(19) United States
(12) Patent Application Publication
(10) Pub. No.: US 2024/0379252 A1
(43) Pub. Date: Nov. 14, 2024

(54) SAFETY PROTECTION DEVICE

(71) Applicant: Mitsubishi Electric Corporation, Chiyoda-ku, Tokyo (JP)

(72) Inventor: Susumu OKUDA, Chiyoda-ku, Tokyo (JP)

(73) Assignee: Mitsubishi Electric Corporation, Chiyoda-ku, Tokyo (JP)

(21) Appl. No.: 18/692,893

(22) PCT Filed: Dec. 1, 2021
(86) PCT No.: PCT/JP2021/044019

§ 371 Date: Mar. 18, 2024

(51) Int. Cl. G21D 3/06

(52) U.S. Cl. CPC G21D 3/06

(57) ABSTRACT

This safety protection device includes: a limitation circuit for performing limitation so that a determination result of a voting circuit does not depend on only outputs of the second determination circuits from outside of the safety protection device, is provided to the voting circuit or at a preceding stage or a subsequent stage of the voting circuit. The voting circuit is imparted with a function of executing a limiting function only when abnormality of a process parameter is detected by a signal from a detector connected to the own device, thereby preventing the function of the own device from being limited or disabled by only a signal from another device.

### TECHNICAL FIELD

The present disclosure relates to a safety protection device.

### BACKGROUND ART

In a safety protection device for a nuclear power plant, in order to achieve high reliability, a detector for detecting a process parameter is multiplexed, and a signal from each of the multiplexed detectors is compared with an actuation setting value for a safety function, to perform determination. Then, using the determination results, a voting circuit determines operation of the safety function.

For example, regarding a logic of the safety function, Patent Document 1 discloses a safety function actuation logic in a system configuration having quadruplex detectors and duplex safety protection devices. Such multiplexed safety protection devices need to be able to execute their functions independently of each other. For example, the logic in Patent Document 1 is configured such that two of signals from four detectors are inputted to a first safety protection device, signals from the other two detectors are inputted to a second safety protection device, and the signals from the detectors are transmitted/received between the duplex safety protection devices. That is, the first safety protection device is capable of outputting an actuation signal for a safety function by a voting circuit (TWO OF FOUR VOTER) based on determination results for two detectors and determination results for the other two detectors inputted from the second safety protection device. This configuration makes such a safety function actuation logic that, even if one of the safety protection devices loses its function, the other safety protection device can execute the safety function.

### CITATION LIST

### Patent Document

Patent Document 1: WO2016/160492

### SUMMARY OF THE INVENTION

### Problem to be Solved by the Invention

In the safety function actuation logic in Patent Document 1, when the first safety protection device receives two determination results indicating abnormality from the second safety protection device, an actuation signal for the safety function is outputted from the voting circuit (TWO OF FOUR VOTER) even if determination results for two detectors inputted to the first safety protection device do not indicate abnormality. However, such an operation does not impair safety and therefore is permitted.

However, if the above safety function actuation logic is applied to a function of limiting the safety function, the safety function is disabled by the determination results from the second safety protection device. Therefore, independency between the duplex devices is not ensured. Thus, the safety function actuation logic cannot be applied to the function of limiting the safety function.

Here, the function of limiting the safety function is as follows. For example, in a pressurized water reactor, boiling of cooling water in a reactor core is prevented by pressurizing the cooling water, and therefore the pressurized water reactor is provided with, as a safety function, a function of performing emergency stop of the nuclear reactor when the pressure of a coolant becomes lower than a certain value. In a process for activating the nuclear power plant from a stop state to an operating state, the pressure of the cooling water is increased along with the output of the nuclear power plant. Therefore, the emergency stop function based on a lowered pressure of the coolant needs to be limited temporarily. This limitation is implemented by such a logic that disables the emergency stop function based on a lowered coolant pressure on a condition that the power plant output is low.

The present disclosure has been made to solve the above problem, and an object of the present disclosure is to provide a safety protection device for limiting a safety function only when abnormality of a process parameter is detected by a signal from a detector connected to an own device.

### Means to Solve the Problem

A safety protection device according to the present disclosure includes: a plurality of first determination circuits which are respectively connected to a plurality of detectors and receive detection values of the detectors, the first determination circuits each being configured to output an actuation demand signal when the detection value is equal to or greater than a predetermined threshold; and a voting circuit which receives outputs of the plurality of first determination circuits and receives outputs of a plurality of second determination circuits from outside of the safety protection device, the voting circuit being configured to determine that a majority is reached when a total number of the outputted actuation demand signals occupies a half or more number in a total number of the inputted outputs of the first and second determination circuits. A limitation circuit for performing limitation so that a determination result of the voting circuit does not depend on only the outputs of the second determination circuits, is provided to the voting circuit or at a preceding stage or a subsequent stage of the voting circuit.

### Effect of the Invention

The safety protection device according to the present disclosure is configured to limit a safety function only when abnormality of a process parameter is detected by a signal from a detector connected to the own device, thereby preventing the function of the own device from being limited or disabled by only a signal from another device.

### BRIEF DESCRIPTION OF THE DRAWINGS

FIG. 1 is a configuration diagram of an execution logic for safety function limitation in a safety protection device according to embodiment 1.

FIG. 2 is a configuration diagram of an execution logic for safety function limitation in a safety protection device according to embodiment 2.

FIG. 3 is a circuit configuration diagram showing an example of a voting circuit according to embodiment 2.

FIG. 4 is a configuration diagram of an execution logic for safety function limitation in a safety protection device according to embodiment 3.

### DESCRIPTION OF EMBODIMENTS

Hereinafter, preferred embodiments of a safety protection device according to the present disclosure will be described with reference to the drawings. The same or corresponding parts are denoted by the same reference characters, and the detailed description thereof is omitted. Also in the other embodiments, parts denoted by the same reference characters will not be repeatedly described.

### Embodiment 1

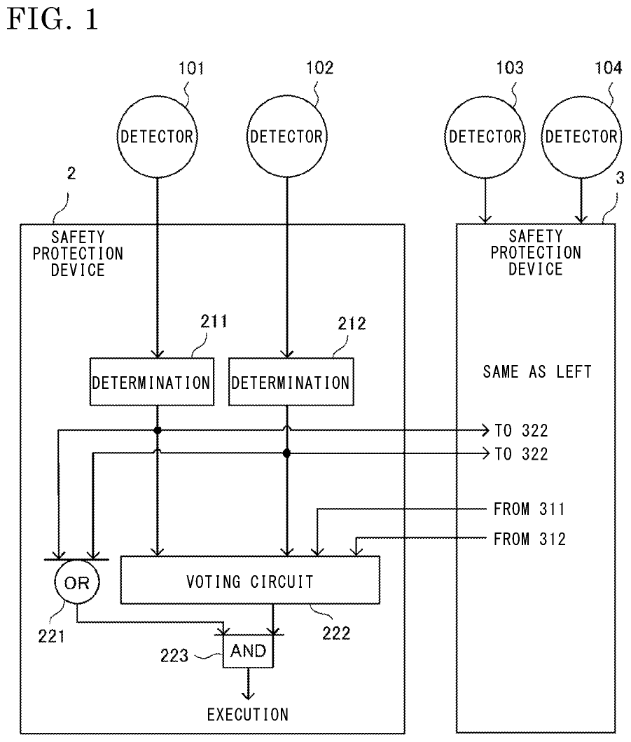

FIG. 1 is a configuration diagram of an execution logic for safety function limitation in a safety protection device according to the present embodiment. Detectors 101 to 104 measure a process parameter such as a flow rate, a water level, a pressure, or a temperature of cooling water used in a plant system of a nuclear power plant, for example. Each process value is in a multiplexed configuration by a plurality of detectors. Here, as an example, the detectors 101 to 104 detect the pressure of the cooling water.

Detection signals from the detectors 101, 102 are inputted to the safety protection device 2, and detection signals from the detectors 103, 104 are inputted to the safety protection device 3. In the safety protection device 2, a determination circuit 211 determines whether or not a pressure value of the detection signal from the detector 101 is equal to or greater than a predetermined threshold, and when the pressure value has become equal to or greater than the threshold, the determination circuit 211 determines that the pressure value is abnormal, and outputs an actuation demand signal. Similarly, a determination circuit 212 determines whether or not a pressure value of the detection signal from the detector 102 is equal to or greater than a predetermined threshold, and when the pressure value has become equal to or greater than the threshold, the determination circuit 212 determines that the pressure value is abnormal, and outputs an actuation demand signal.

In the safety protection device 3, a determination circuit 311 determines whether or not a pressure value of the detection signal from the detector 103 is equal to or greater than a predetermined threshold, and when the pressure value has become equal to or greater than the threshold, the determination circuit 311 determines that the pressure value is abnormal, and outputs an actuation demand signal. Similarly, a determination circuit 312 determines whether or not a pressure value of the detection signal from the detector 104 is equal to or greater than a predetermined threshold, and when the pressure value has become equal to or greater than the threshold, the determination circuit 312 determines that the pressure value is abnormal, and outputs an actuation demand signal.

A voting circuit 222 of the safety protection device 2 outputs a safety signal when, of inputted signals from the determination circuits, a half or more number of signals are actuation demand signals. In the present embodiment, as shown in FIG. 1, when actuation demand signals from a plurality of (two or more) determination circuits out of the four determination circuits 211, 212, 311, 312 are inputted, a safety signal is outputted (TWO OF FOUR VOTER). However, a configuration is made such that limitation of a safety protection operation of the safety protection device 2 is executed only when either of the determination circuits 211, 212 outputs an actuation demand signal.

For achieving the above configuration, as shown in FIG. 1, a configuration is made such that a logical conjunction (AND circuit 223) of an output of the voting circuit 222 and an output of a logical disjunction (OR circuit 221) of outputs of the determination circuits 211, 212 becomes an output of the safety protection device 2. Thus, limitation of a safety protection operation of the safety protection device 2 is prevented from being executed by only outputs from the outside of the safety protection device 2, e.g., actuation demand signals from the determination circuits 311, 312 of the safety protection device 3.

The safety protection device 3 is also configured in the same manner as the safety protection device 2. In this case, outputs of the determination circuits 211, 212 are inputted to a voting circuit 322 in the safety protection device 3.

As described above, the voting circuit is imparted with a function of executing a limiting function only when abnormality of a process parameter is detected by a signal from a detector connected to the own device, thereby preventing the function of the own device from being limited or disabled by only a signal from another device.

### Embodiment 2

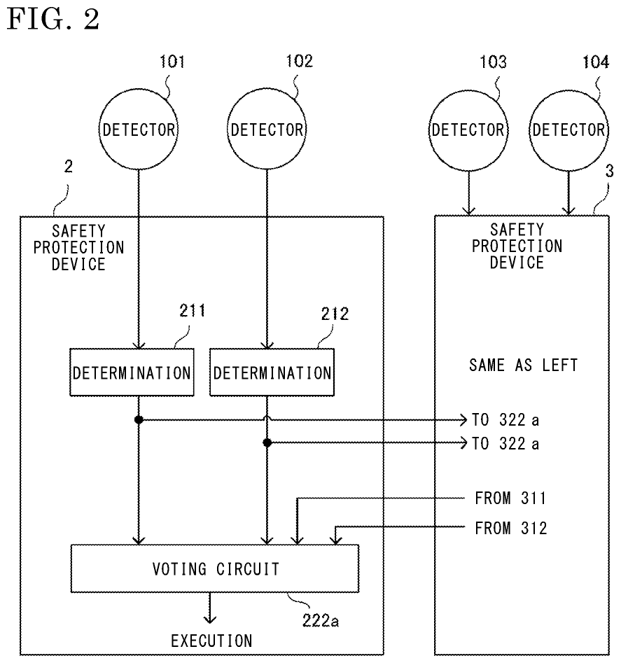

FIG. 2 shows the configuration of an execution logic for safety function limitation in a safety protection device according to the present embodiment. The configurations and operations of the detectors 101 to 104 and the configurations and operations of the determination circuits 211, 212, 311, 312 are the same as those in embodiment 1, and therefore the description thereof is omitted.

A voting circuit 222a outputs a safety signal when, of inputted signals from the determination circuits, a half or more number of signals are actuation demand signals. In the present embodiment, when actuation demand signals are inputted from at least two determination circuits out of the four determination circuits 211, 212, 311, 312, limitation of a safety protection operation of the safety protection device 2 is executed (TWO OF FOUR VOTER). However, a circuit configuration is made such that a signal is not outputted with only actuation demand signals from the determination circuits 311, 312 of the safety protection device 3.

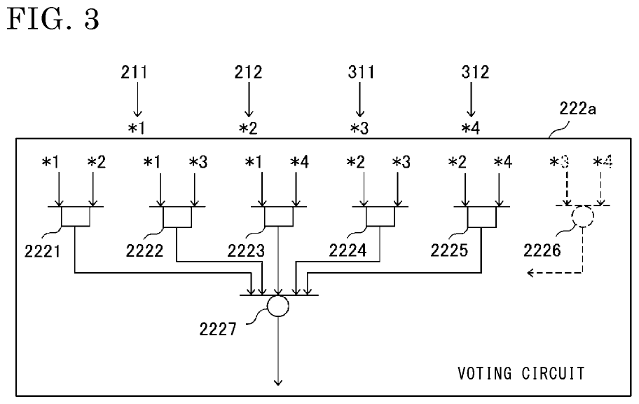

A specific circuit configuration of the voting circuit 222a is shown in FIG. 3. The voting circuit shown in FIG. 3 is configured to output a signal by an OR circuit 2227 to which the following signals are inputted.
(1) An output of an AND circuit 2221 which receives inputs from the determination circuit 211 and the determination circuit 212
(2) An output of an AND circuit 2222 which receives inputs from the determination circuit 211 and the determination circuit 311
(3) An output of an AND circuit 2223 which receives inputs from the determination circuit 211 and the determination circuit 312
(4) An output of an AND circuit 2224 which receives inputs from the determination circuit 212 and the determination circuit 311
(5) An output of an AND circuit 2225 which receives inputs from the determination circuit 212 and the determination circuit 312

It is noted that a combination of signals from the determination circuit 311 and the determination circuit 312 is constituted of only signals inputted from the safety protection device 3, and therefore is not inputted to the OR circuit 2227.

The safety protection device 3 is also configured in the same manner as the safety protection device 2. In this case, outputs of the determination circuits 211, 212 are inputted to a voting circuit 322a in the safety protection device 3.

With the above configuration, the voting circuit is configured to execute a limiting function only when abnormality of a process parameter is detected by a signal from a detector connected to an own device, thereby preventing the function of the own device from being limited or disabled by only a signal from another device. In addition, as compared to embodiment 1, it is not necessary to add a separate circuit to the voting circuit, and thus the circuit configuration can be simplified and downsized.

### Embodiment 3

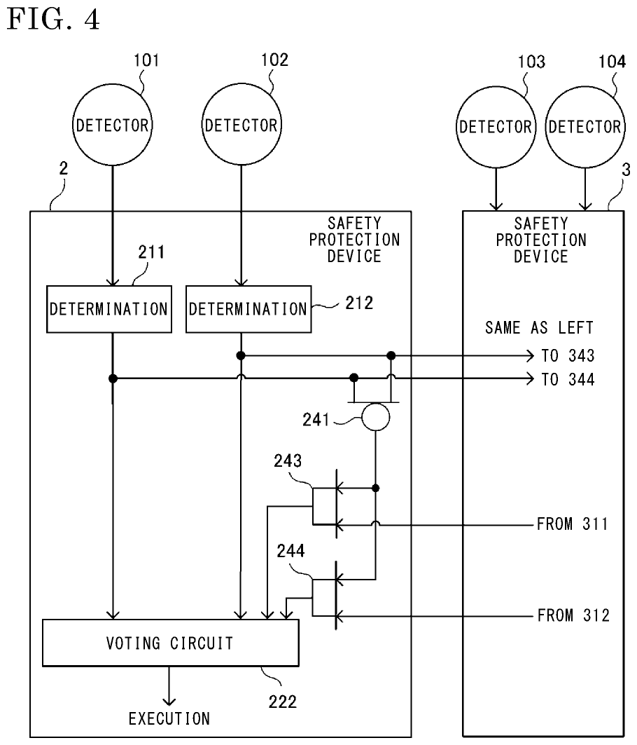

FIG. 4 shows the configuration of an execution logic for safety function limitation in a safety protection device according to the present embodiment. The configurations and operations of the detectors 101 to 104 and the configurations and operations of the determination circuits 211, 212, 311, 312 and the voting circuit 222 are the same as those in embodiment 1, and therefore the description thereof is omitted.

Signals from the determination circuits 311, 312 of the safety protection device 3, together with an output of an OR circuit 241 which receives output signals from the determination circuits 211, 212 of the safety protection device 2, are inputted to AND circuits 243, 244, and outputs of the AND circuits 243, 244, together with outputs of the determination circuits 211, 212, are inputted to the voting circuit 222. Thus, actuation is prevented from occurring without a signal from either of the determination circuits 211, 212 of the safety protection device 2. That is, a configuration is made such that limitation of a safety protection operation of the safety protection device 2 is executed only when, of the signals inputted from the determination circuits to the voting circuit 222, a half or more number of signals are actuation demand signals and an actuation demand signal is outputted from either of the determination circuits 211, 212.

The safety protection device 3 is also configured in the same manner as the safety protection device 2. In this case, outputs of the determination circuits 211, 212 are respectively inputted to AND circuits 343, 344 in the safety protection device 3.

With the above configuration, the voting circuit is imparted with a function of executing a limiting function only when abnormality of a process parameter is detected by a signal from a detector connected to the own device, thereby preventing the function of the own device from being limited or disabled by only a signal from another device.

In embodiments 1 to 3, the number of the safety protection devices is two, the number of detectors is four, and the number of the determination circuits is four. However, the numbers of these are not limited thereto.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

2, 3 safety protection device
101, 102, 103, 104 detector
211, 212, 311, 312 determination circuit
222, 222a voting circuit

1. A safety protection device comprising:
a plurality of first determination circuits which are respectively connected to a plurality of detectors and receive detection values of the detectors, the first determination circuits each being configured to output an actuation demand signal when the detection value is equal to or greater than a predetermined threshold; and
a voting circuit which receives outputs of the plurality of first determination circuits and receives outputs of a plurality of second determination circuits from outside of the safety protection device, the voting circuit being configured to determine that a majority is reached when a total number of the outputted actuation demand signals occupies a half or more number in a total number of the inputted outputs of the first and second determination circuits, wherein
a limitation circuit for performing limitation so that a determination result of the voting circuit does not depend on only the outputs of the second determination circuits, is provided to the voting circuit or at a preceding stage or a subsequent stage of the voting circuit.

2. The safety protection device according to claim 1, wherein
the limitation circuit is configured not to output an output of the voting circuit to outside of the safety protection device when a determination result of the voting circuit depends on only the outputs of the second determination circuits.

3. The safety protection device according to claim 2, wherein
the limitation circuit is a circuit that outputs a logical conjunction of the output of the voting circuit and an output of a logical disjunction of the plurality of first determination circuits.

4. A safety protection device comprising:
a plurality of first determination circuits which are respectively connected to a plurality of detectors and receive detection values of the detectors, the first determination circuits each being configured to output an actuation demand signal when the detection value is equal to or greater than a predetermined threshold; and
a voting circuit which receives outputs of the plurality of first determination circuits and receives outputs of a plurality of second determination circuits from outside of the safety protection device, the voting circuit being configured to determine that a majority is reached when a total number of the outputted actuation demand signals occupies a half or more number in a total number of the inputted outputs of the first and second determination circuits, without reflecting, in voting determination, determination that depends on only the outputs of the second determination circuits.

5. A safety protection device comprising:
a plurality of first determination circuits which are respectively connected to a plurality of detectors and receive detection values of the detectors, the first determination circuits each being configured to output an actuation demand signal when the detection value is equal to or greater than a predetermined threshold;
a voting circuit which receives outputs of the plurality of first determination circuits and receives outputs of a plurality of second determination circuits from outside of the safety protection device, the voting circuit being configured to determine that a majority is reached when a total number of the outputted actuation demand signals occupies a half or more number in a total number of the inputted outputs of the first and second determination circuits; and
a limitation circuit which limits inputs of the outputs of the second determination circuits to the voting circuit so that a determination result of the voting circuit does not depend on only the outputs of the second determination circuits.

6. The safety protection device according to claim 5, wherein the limitation circuit is a circuit that inputs, to the voting circuit, a logical disjunction of the outputs of the plurality of first determination circuits and a logical conjunction of the outputs of the second determination circuits.
